(19) United States
(12) Patent Application Publication
(10) Pub. No.: US 2008/0197904 A1
(43) Pub. Date: Aug. 21, 2008

(54) Circuit Arrangement for Switching a Load

(75) Inventor: Stephan Bolz, Pfatter (DE)

Correspondence Address: LERNER GREENBERG STEMER LLP, P O BOX 2480, HOLLYWOOD, FL, 33022-2480, US

(73) Assignee: SIEMENS VDO AUTOMOTIVE AG, Regensburg (DE)

(21) Appl. No.: 11/917,292

(22) PCT Filed: May 15, 2006
(86) PCT No.: PCT/EP2006/062313

§ 371 Date: Dec. 12, 2007

(30) Foreign Application Priority Data
Jun. 14, 2005 (DE) 10 2005 027 442.0

(51) Int. Cl. H03K 5/08; H03K 5/04

(52) U.S. Cl. 327/180; 327/177

(57) ABSTRACT

A circuit arrangement for switching a load includes at least one at least partially inductive load, at least one high side switch with a controlled path connected in series with the load and between supply terminals for a supply voltage. At least one freewheeling diode is connected with a first tap between the high side switch and the load. At least one clamp circuit is connected to a control terminal of the high side switch and is used to limit the control potential applied to the control terminal to a first pre-determined voltage value when the high side switch is switched off.

The invention relates to a circuit arrangement for switching a load, in particular an inductively embodied load.

Circuit arrangements of this kind are used, for example, in automotive electronics, in which there is increasingly the demand to be able to switch loads as rapidly as possible. A particular focus here is on inductively embodied loads. A known circuit arrangement for controlling an inductive load is described, for example, in the German patent DE 102 52 827 B3.

The problems underlying the present invention and the problem definition that accompanies them will be described below by way of example with reference to an inductive load to be switched in an electromagnetic injection valve, but without restricting the invention thereto.

Electromagnetic injection valves have an inductive valve coil by means of which the valve needle can be opened and closed electromagnetically very rapidly such that the quantity of fuel injected into the cylinder can be controlled in a precise and highly dynamic manner by this means. The structure and mode of operation of such injection valves is widely known so these will not be considered in detail below. This valve coil is intended to be switched dynamically, i.e. as rapidly and free of delay as possible, making it necessary to build up a current as fast as possible. Due to the relatively large inductance inherent in the valve coil, this is possible only with an increased operating voltage of, for example, 48 volts. Therefore, to rapidly switch the valve coil, power switches, such as for example power MOSFETs, are preferably used.

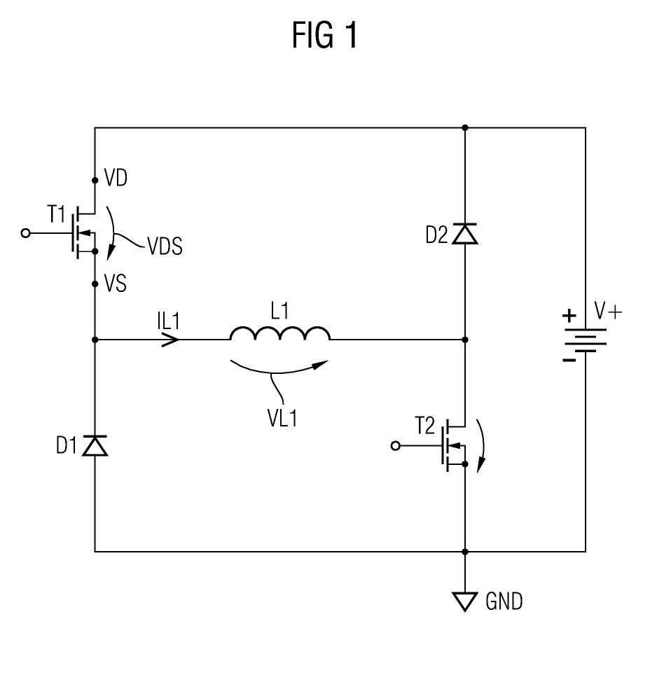

In order to illustrate the general problems, a circuit arrangement for the PWM operation of an inductive valve coil will be explained with reference to FIG. 1 below. FIG. 1 shows a power MOSFET T1 embodied as a high-side switch for switching the valve coil L1 of the injection valve which can be operated in PWM mode by means of an appropriate PWM control. The inductance L1 can be connected to a supply voltage V+ via the high-side switch T1 and a further power MOSFET T2 embodied as a low-side switch. In addition, a free-wheeling diode D1 is provided for the PWM mode and a recuperation diode D2 for reducing the voltage when switching off.

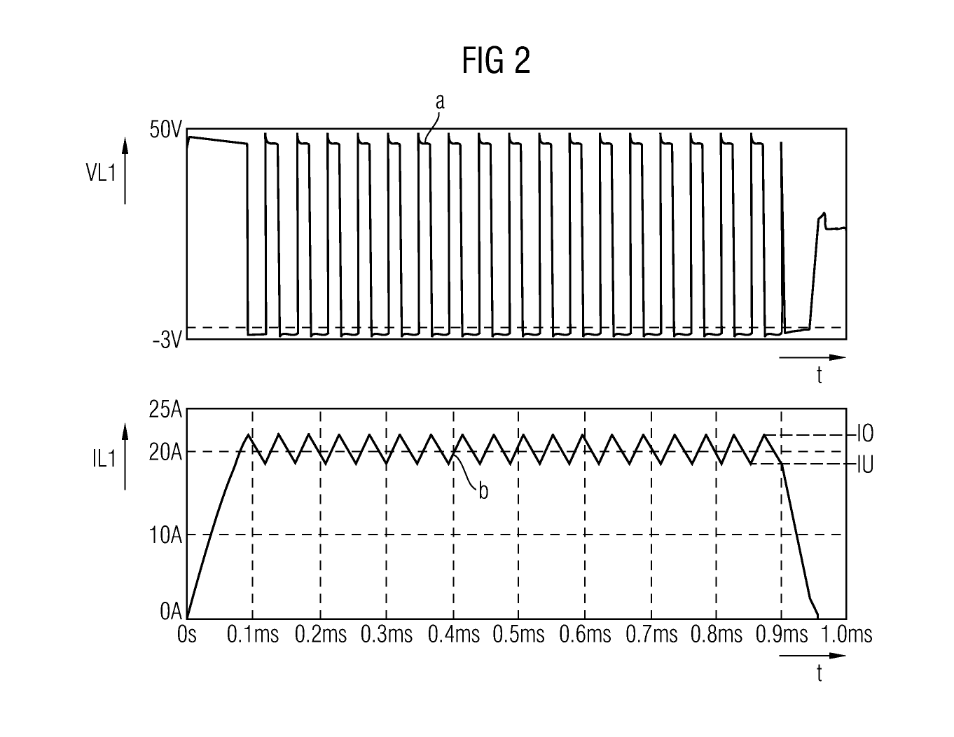

FIG. 2 shows signal-time diagrams with the valve coil from 17 FIG. 1 in PWM mode, the valve voltage VL1 being represented by curve a and the valve current IL1 by curve b. At the start of the switch-on process, both power MOSFETs T1, T2 are closed. The supply voltage V+ is now applied to the valve coil L1. The current IL1 through the valve coil L1 increases very rapidly. When an upper target value IO for the current is reached, the high-side switch T1 is switched off. The coil current IL1 now flows via the free-wheeling diode D1, the inductance L1 and the low-side switch T2, as a result of which the coil current IL1 slowly decreases. When the coil current IL1 reaches a lower target value IU, then the high-side switch T1 is switched on again, whereupon the coil current IL1 increases again. By repeatedly switching the high-side switch T1 on and off, the coil current can in this way be held during the switched-on period T1 at an approximately constant value that lies between the upper and the lower target current value IO, IU. At the end of the switched-on period T, both power MOSFETs T1, T2 are switched off. The inductance L1 is then discharged via the free-wheeling diode D1 and the recuperation diode D2 into the supply voltage source.

The circuit arrangement represented in FIG. 1 represents an ideal case, i.e. one in which parasitic influences, such as for example the influence of connecting leads, are not taken into account. These power components used in the case of a valve coil are typically arranged on a printed circuit board and consequently spatially separated from the injection valve and electrically connected thereto only via corresponding connecting leads or PCB tracks. Depending on the length of these connecting leads or PCB tracks, these constitute greater or lesser parasitic line inductances.

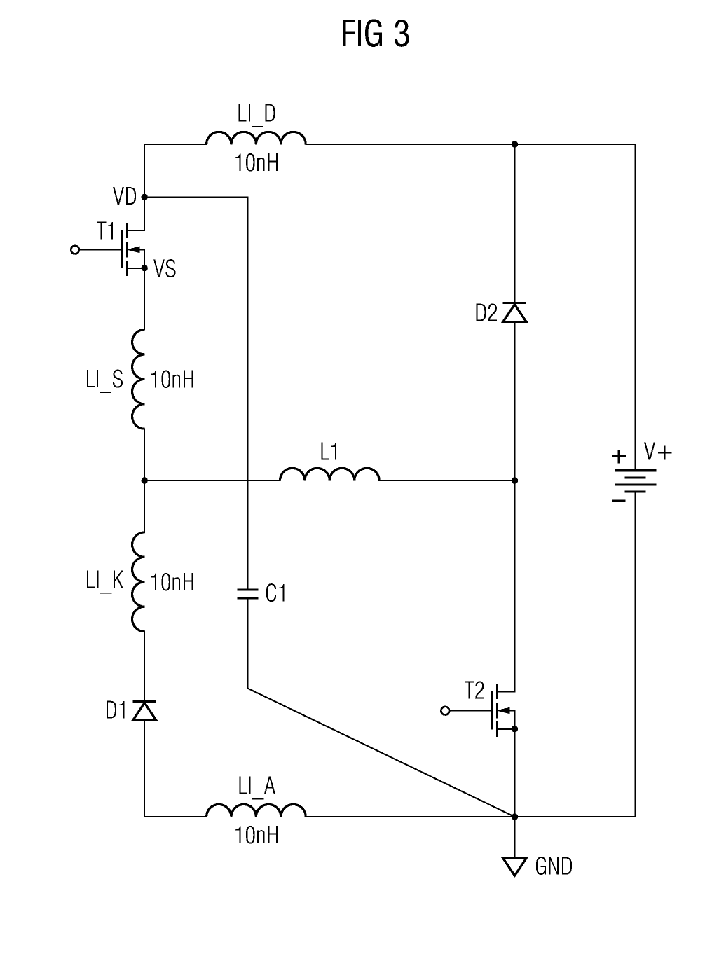

To illustrate these general problems, FIG. 3 of the drawings shows a circuit arrangement for the PWM operation of a valve coil of an inductive injection valve with parasitic line inductances LI_D, LI_S, LI_K, LI_A. These line inductances are produced from the lines between the drain terminal of the power MOSFET T1 and the positive supply terminal (LI_D), the source terminal of the power MOSFET T1 and the valve coil L1 (LI_S), the cathode and anode terminals of the free-wheeling diode D1 and the grounding terminal (LI_A) or the source terminal of the power MOSFET T1 (LI_K). Typical values for the line inductances produced by the connecting lines lie in the range of about 10 nH. Since, however, it is not always possible in practice to design the appropriate lines so as to be as short as possible, inductances emerge as a result which are not negligible and which, if the high-side switch is switched off rapidly, are an obstacle to a rapid transfer of the coil current IL1 from the power MOSFET T1 to the free-wheeling diode D1. With a blocking capacitor C1 which is arranged between the drain terminal of the power MOSFET T1 and ground, only the effect of the connecting lead inductance LI_D is suppressed, but not that of the other connecting lead inductances LI_S, LI_K, LI_A.

The power MOSFETs T1 used, which are designed for operating voltages of from several tens of volts to several hundred volts typically have a cell field comprising a large number of individual cells, an individual transistor being arranged in each individual cell and the large number of individual transistors being switched in parallel with one another in relation to their controlled paths. The current-carrying capacity of such a power MOSFET depends on the one hand on physical parameters such as, for example, the doping concentration in the channel and drift region, as well as on the number of individual transistors arranged in parallel in relation one another. The power MOSFET T1 produced from the large number of individual transistors is designed for a (drain-source) breakdown voltage which substantially depends on the dimensioning of the drift region, i.e. the thickness and doping concentration thereof. The thicker the drift region is or the lower its doping concentration is, the higher is the resulting switch-on resistance RDSon, which substantially determines the breakdown voltage of a power MOSFET. In contemporary power MOSFETs, the drift region is composed of multiple lowly doped epitaxial layers (e.g. three to seven), whereby for power MOSFETs with a very high breakdown voltage a correspondingly large number of epitaxial layers are provided.

Power MOSFETs sold today are designed for different power classes and thus for different breakdown voltages. The general rule is that the higher the breakdown voltage of a power MOSFET is intended to be, the more expensive it will also be, since the power MOSFET will then also have to have a corresponding number of epitaxial layers.

The voltage class for a power MOSFET which is to be used with a battery voltage of 48 volts for switching an inductive injection valve is now chosen such that it has a breakdown voltage of at least 48 volts. However, using a power MOSFET which in terms of the breakdown voltage is over-dimensioned with too large a breakdown voltage should where possible also be avoided, as this may possibly require a power MOSFET of a higher voltage class that is consequently also more cost-intensive. Consequently, power MOSFETs with breakdown voltages close to the operating voltage are used for switching the inductive load.

When using a circuit arrangement for the PWM operation of an inductive load in accordance with FIGS. 1 and 3, the following problem arises:

In the ideal case (see FIG. 1), when the high-side switch T1 is in the switched-off state, its drain-side potential VD≈48 volts and its source-side potential VS≈−0.7 volts. Consequently, in the switched-off state, the drain-source voltage VDS decreasing over the controlled path of the high-side switch T1 amounts to:

VDS=VD−VS=48.7 volts

The power MOSFET D1 must therefore ideally be designed at least for a breakdown voltage VDB of >48.7 volts.

In reality (FIG. 3), however, the source-side potential is not VS≈−0.7 volts, which corresponds to the flow voltage VD1 of the free-wheeling diode D1, but is significantly greater in magnitude, due to the parasitic line inductance LI_S, LI_K, LI_A. When the inductance L1 is switched off, these line inductances LI_S, LI_K, LI_A cause, on account of the stored energy, a negative voltage peak VNEG which results in the source-side potential VS being very much more negative than the flow voltage VD1 of the free-wheeling diode D1. This voltage VNEG is given as follows:

VDS=V++VD1+VNEG

Caused by the line inductances, the source-side potential VS of the high-side switch T1 is given as follows:

VS=VD1+VNEG

When the various line inductances have a magnitude of, for example, 10 nH, the source-side potential is VS≈−9.4 volts. Consequently, the drain-source voltage VDS at these line inductances is in reality:

VDS=48 volts−(−9.4 volts)−57.4 volts

In a power MOSFET whose breakdown voltage lies somewhat above the operating voltage V+=48 volts this would necessarily lead to a breakdown of the power MOSFET. In order to prevent this, a power MOSFET is required which is designed for a higher dielectric strength and thus, for example, for a next-higher voltage class.

However, the further problem has to be taken into account that, beside the dependence of the breakdown voltage on the thickness and doping of the drift region, this breakdown voltage also depends in a directly proportional manner on the temperature. The lower the temperature, the lower the breakdown voltage will also be. An added complication is that at very low temperatures the voltage peak VNEG generated by the parasitic line inductances is reached very much more rapidly, which overall increases the drain-source voltage VDS even more. The cause of this is that a MOSFET switches more rapidly at low temperatures than at high temperatures. Together with the somewhat lower breakdown voltage, this can rapidly lead, particularly at low temperatures, to a power MOSFET that has a sufficiently high breakdown voltage in normal operating mode no longer having a sufficiently high breakdown voltage at very low temperatures. As a consequence, the power MOSFET would break down, which in a power MOSFET with a cell-type structure is expressed in a breakdown of individual transistor cells and would lead to a functional failure of the entire power MOSFET. This problem occurs in particular in high-side switches which can be controlled by field effect.

The overall consequence of this is that, particularly in automotive applications which have to be designed for a large temperature range from −50° C. to 150° C., the power MOSFETs used have to be very markedly over-dimensioned in terms of their breakdown voltage in order to a prevent an increased failure rate. However, this brings with it cost disadvantages which, particularly in automotive applications, should be avoided where possible.

A further problem emerges as follows: the magnitude of the negative voltage peak VNEG depends substantially on the coil current IL1, the switching speed between the power MOSFET T1 and the free-wheeling diode D1 and the parasitic line inductances that are produced by the layout. If one of these parameters changes, for example if the layout of the circuit arrangement is changed as part of a re-design, then the value of the voltage peak VNEG may also change in an unintended manner. If, due to this, the drain-source voltage VDS increases, then this can have a considerable impact on product quality, especially taking into account the above remarks. In order to prevent this, a costly and time-consuming measurement of this voltage peak VNG is carried out on the respective serial circuit arrangements. Besides the associated time expenditure, this also leads in an unwanted manner to an additional increase in cost of the corresponding circuit arrangement.

A further problem arises due the fact that the negative voltage peak VNEG causes an increase in electromagnetic (EMC) emission on the connecting lead to the injection valve. Particularly in applications in automotive electronics, this can bring about unwanted effects in other circuit components. While filters in the connecting lead to the injection valve can be used to reduce the EMC emission, these represent an additional switching outlay, which renders the whole circuit arrangement more expensive in terms of circuit engineering and thus more cost-intensive. For this reason, EMC emission should where possible be avoided, particularly in automotive electronics.

Against this background, the object of the present invention is to provide a circuit arrangement for switching an inductive load that is as cost-effective as possible and in particular as simple as possible. A further object of the invention is to reduce as far as possible the voltage peaks generated by parasitic line inductances when switching off. A further object is to provide a lower EMC emission for a circuit arrangement for switching inductive loads.

According to the invention, at least one of the aforementioned objects is achieved in a circuit arrangement comprising the features of claim 1.

The idea on which the present invention is based is to undertake a clamping and consequently a limiting of the control potential of the high-side switch to a predetermined voltage value. When the control terminal is discharged, the control terminal of the high-side switch, and thus also its load-side terminal (e.g. the source terminal), consequently remains clamped to the predetermined voltage value. This can be implemented in a very simple low-cost clamp circuit.

The knowledge on which the invention is based is that, in the switching of an inductive load, the crucial factor when switching off the controllable switching transistor, in particular a power MOSFET, embodied as a high-side switch is not a switching-off process that is as rapid as possible. It suffices instead if the switching-off process is somewhat delayed, as a result of which, however, parasitic line impedances are advantageously discharged and these consequently lead to a reduced extent to unwanted voltage peaks at the load-side output of the high-side switch.

Clamping the control terminal according to the invention now to a predetermined potential also avoids an undesirably high charging of the control terminal of the high-side switch. Due to this, the potential applied to the load-side terminal (source) of the high-side switch is also limited. The influence of the parasitic line inductances cannot, however, be completely avoided. The potential appearing at the load-side terminal of the high-side switch is, however significantly lower if a clamp circuit according to the invention is used than without a clamp circuit. On switching off, the loading of the high-side switch, i.e. the voltage dropping over its controlled path, is thus significantly reduced compared with such applications without clamp circuits.

The accompanying advantages of such a circuit arrangement are obvious:

Especially in the automotive sphere, in which the corresponding components have to be designed for a very high temperature range, this is of particular advantage since high-side switches with a significantly reduced breakdown voltage may possibly be used here. Due to this, high-side switches with lower dielectric strength and consequently of a lower voltage class can be used which are consequently also lower in cost. The entire circuit arrangement can consequently be supplied at lower cost, which, particularly in the automotive industry, where the cost factor is frequently a deciding criterion, brings with it a key operating advantage.

A further very substantial advantage is that, by virtue of the clamp circuit, the potential arising at the load-side terminal of the high-side switch now exhibits reduced voltage peaks, which leads directly to a significant reduction in EMC emission.

A further advantage is that the amplitude of the remaining potential, produced by a switching-off process, at the load-side output of the high-side switch is by virtue of the corresponding circuit topography very well definable and consequently very readily determinable. Costly and possibly difficult measurements in production to determine this potential can consequently be waived.

A further advantage is that the functional principle of the clamp circuit can be applied to a wide variety of control circuits which have a corresponding driver for controlling a high-side switch.

Advantageous embodiments and further developments of the invention will emerge from the further subclaims and from the description with reference to the drawings.

In an especially preferred (in circuit-engineering terms) and in particular very simple embodiment, the clamp circuit contains a simple limiter diode. This limiter diode is polarized downstream relative to the control terminal of the high-side switch and serves to clamp the control potential of the high-side switch to a flow potential predetermined by the limiter diode. Consequently, for the clamp circuit functionality only a simple low-power diode is required here, which makes the clamp circuit according to the invention particularly attractive, above all on cost grounds.

In a typical embodiment, the high-side switch is embodied as a switching transistor which can be controlled by field effect, for example as a MOSFET or as a JFET.

The circuit arrangement according to the invention has in relation to the energy supply a first supply terminal with a first supply potential and a second supply terminal with a second supply potential. For the controllable switching transistor embodied as a high-side switch to function, it is necessary for the first supply potential to be at least greater than the second supply potential. Typically, the energy supply is a battery which is designed so as to provide a battery DC voltage. In this case, the first supply potential designates a positive potential, while the second supply potential designates a negative potential or a ground reference potential.

In a particularly preferred embodiment, the clamp circuit or its limiter diode is arranged between the control terminal of the high-side switch and the second supply terminal. In this way, the potential at the load-side terminal of the high-side switch is limited.

In a further, likewise typical, embodiment, the free-wheeling diode for free-wheeling when the high-side switch is switched off is arranged between the first tap and the second supply terminal and is connected downstream relative to the first tap. In this way, the energy stored in the inductive load can, in an operating mode in which the high-side switch is open, be discharged via this free-wheeling diode.

In a very advantageous embodiment, a second switching transistor and a recuperation diode are provided. The second switching transistor is embodied as a low-side switch, the controlled path of which is arranged in series in relation to the load. The recuperation diode is connected at a tap between the second switching transistor and the load. With the circuit arrangement in PWM mode, this low-side switch is preferably switched on such that, when the high-side switch is switched on, the inductive load can be connected via the low-side switch to the supply voltage and can consequently be charged up. When the high-side switch is switched off, the inductive load is then slowly discharged via the free-wheeling diode and the low-side switch. The recuperation diode serves the purpose of discharging the inductive load rapidly against the supply voltage, provided the entire circuit arrangement is in switched-off status and the high-side switch and the low-side switch are consequently switched off. For this purpose, the recuperation diode is arranged between the second tap and the first supply terminal and switched in the reverse direction relative to the second tap.

In a typical embodiment, the high-side switch and/or the low-side switch is/are embodied as power MOSFETs. For reasons of cost, N-channel transistors are particularly suitable here; compared with p-channel transistors, they have a smaller chip surface for the same transistor properties and are consequently preferable in particular on cost grounds.

In a likewise preferable embodiment, at least the free-wheeling diode is embodied as a power diode. Additionally or alternatively, the recuperation diode can also be embodied as a power diode.

In a typical application, the circuit arrangement is designed for the alternate rapid switching on and off of an inductive load and in particular for the PWM operation of the coil inductance of an electromagnetic injection valve. This coil inductance thus forms the inductive load that is to be switched via the high-side switch. Any other applications, for example for 3-phase frequency converters for operating electric motors/generators with electronic commutation, bidirectional DC/DC converters for controlling electromagnetic valves and such like, would, however, also be conceivable.

In a preferred embodiment, a control circuit which has a driver is provided at least for controlling the high-side switch. For dynamically switching the high-side switch, the driver generates a control current, for example a PWM-modulated control current. The driver is embodied as a power driver. The control circuit is preferably embodied as an integrated control circuit, i.e. the elements of the driver are implemented at least partially in a single semiconductor chip.

In a second embodiment, a clock generator connected upstream of the driver is provided which can, for example, be an integral part of the control circuit itself. The clock generator generates a clock signal for the driver for adjusting the pulse duty cycle of the control current. A simple oscillator, for example, a quartz oscillator is preferably used as the clock generator.

In a preferred embodiment, the control circuit has a discharging circuit which, for switching off the high-side switch, generates a discharge current via which the control terminal of the high-side switch can be discharged to a switching-off process of the high-side switch. Preferably, but not necessarily, the discharging circuit has a switching diode which is arranged downstream relative to the control terminal of the high-side switch and via which, during a switching-off process of the high-side switch, the discharge current for discharging the control terminal of the high-side switch can flow at least for a short period. In a particularly advantageous (since low-cost) embodiment, the switching diode and the limiter diode are embodied as an integrated double diode, the cathodes of which are short-circuited to one another and arranged together on a semiconductor chip.

In a preferred embodiment, the control circuit and/or the clamp circuit has a circuit arrangement for rounding the potential at the load-side output of the high-side switch, which circuit arrangement causes, during a switch-off process of the high-side switch and thus upon transition to free-wheeling, the control potential VG and thus also the potential at the load-side output of the high-side switch to decrease more slowly.

In a particularly preferred development of the invention, the free-wheeling diode, the high-side switch and the inductive load form a PWM unit. The circuit arrangement has a large number of such PWM units. Preferably, but not necessarily, a (single) low-side switch and a (single) recuperation diode are provided which are assigned to all the PWM units. By means of this circuit arrangement, various inductive loads, for example the various electromagnetic injection valves of an internal combustion engine, can be operated using one and the same circuit arrangement. It can also be particularly advantageous if for each of the various PWM units a single control circuit and also a single driver is provided which controls, for example via suitable switching means, each of the various control terminals of the high-side switches of the different PWM units.

The invention will be described below with the aid of the exemplary embodiments indicated in the schematic figures in the drawings, in which:

FIG. 1 shows a circuit arrangement for the PWM operation of a valve coil, to illustrate the general problems;

FIG. 2 shows signal-time diagrams for the valve voltage (curve a) and the valve current (curve b) during PWM operation of the valve coil in FIG. 1;

FIG. 3 shows a circuit arrangement according to FIG. 1 with parasitic line inductances, to illustrate the general problems;

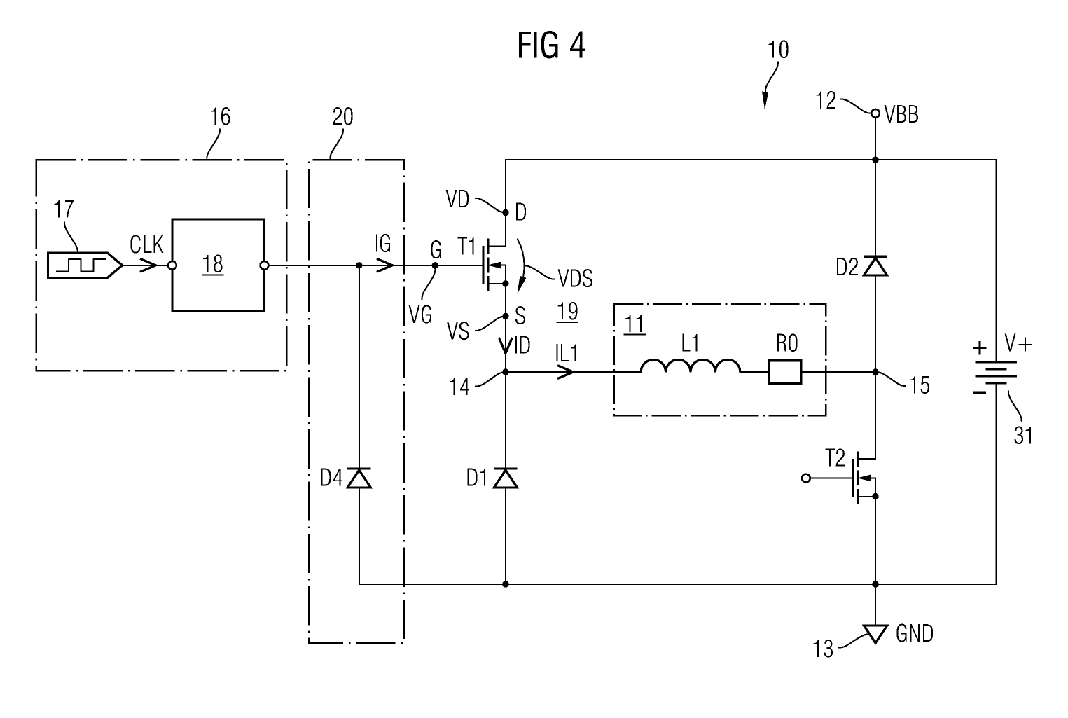

FIG. 4 shows a first, general exemplary embodiment of an inventive circuit arrangement for the PWM operation of an inductive load.

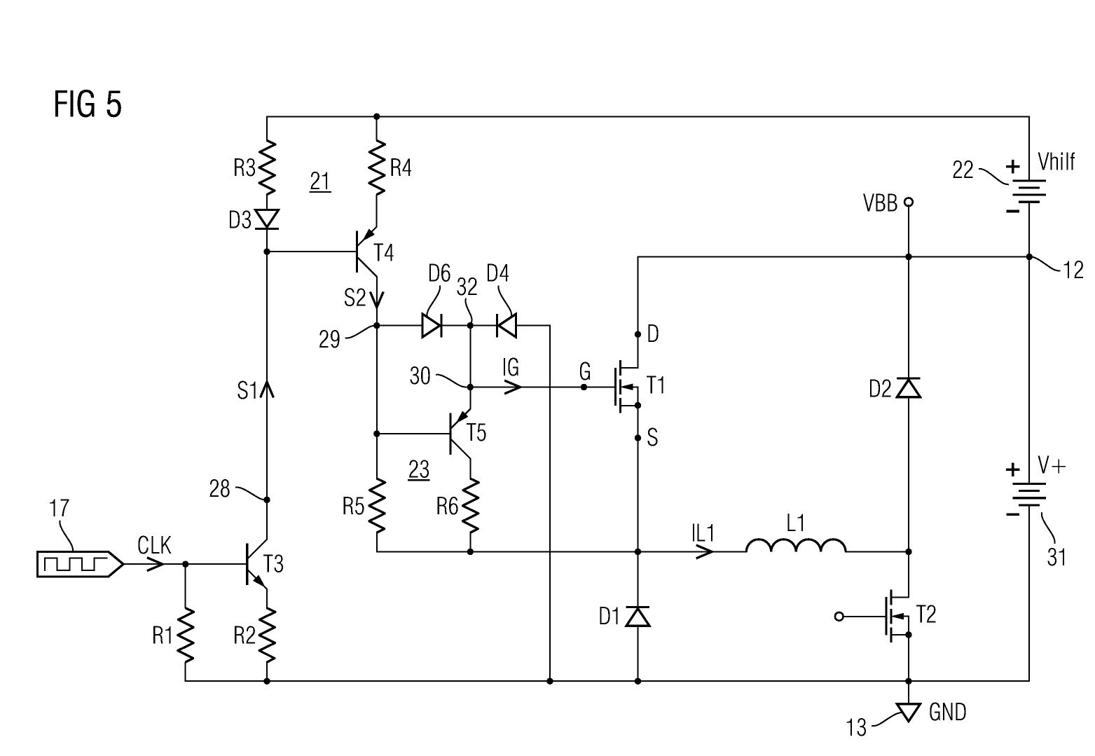

FIG. 5 shows a second, detailed exemplary embodiment of an inventive circuit arrangement for the PWM operation of an inductive load.

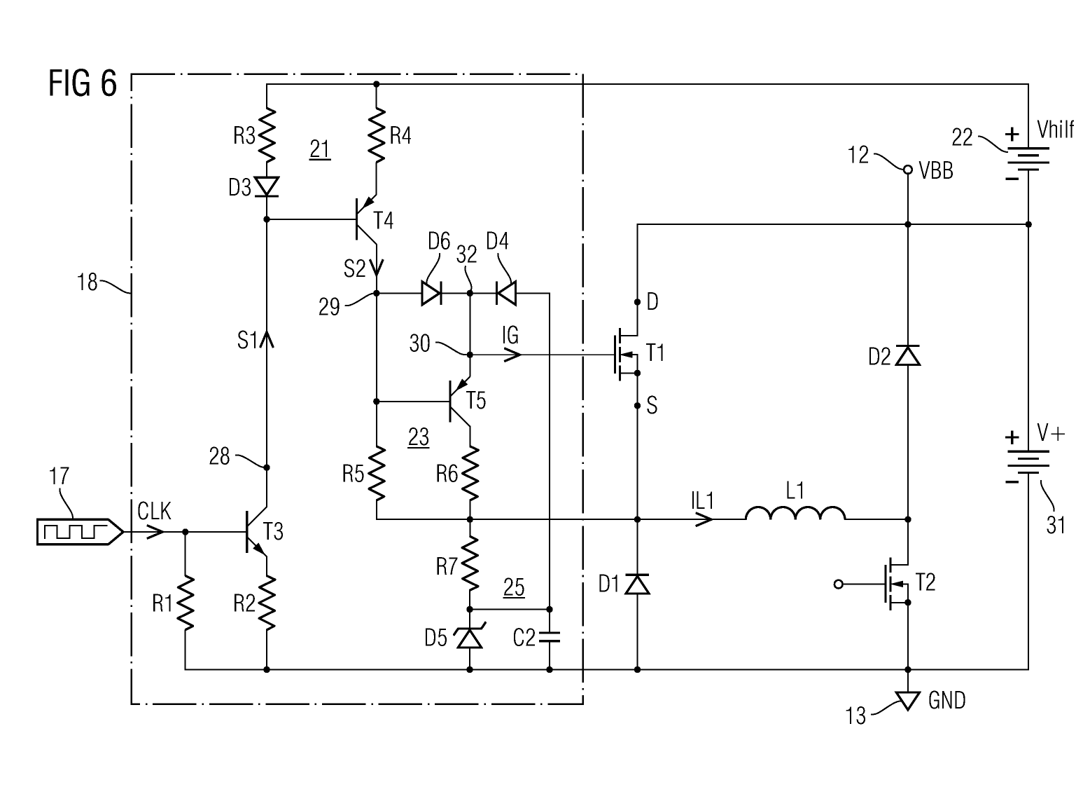

FIG. 6 shows a third, detailed exemplary embodiment of an inventive circuit arrangement for the PWM operation of an inductive load.

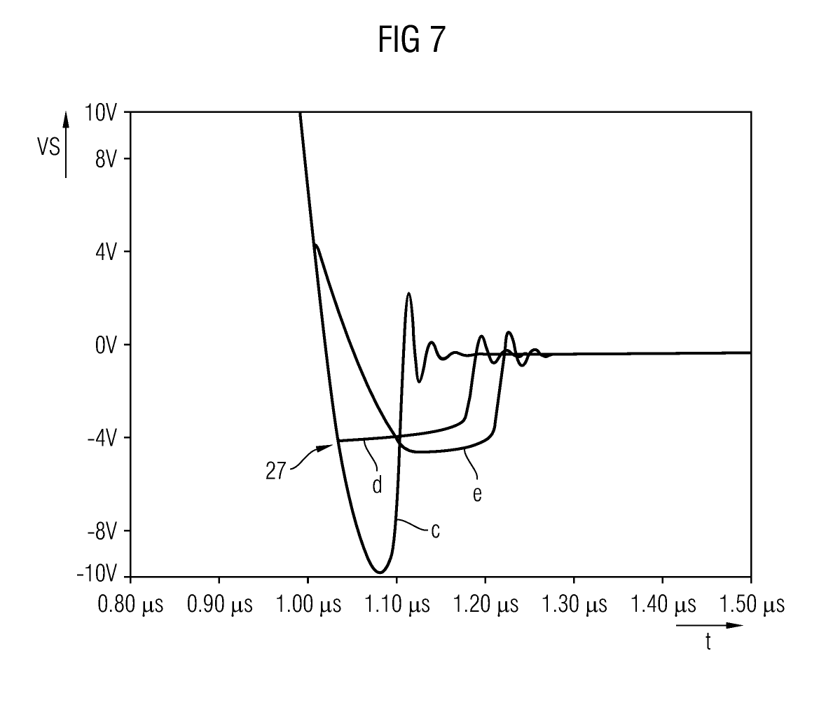

FIG. 7 shows signal-time diagrams for the source potential applied to the source terminal of the high-side switch without a clamp circuit (curve c), with an inventive clamp circuit according to FIG. 4 (curve d) and with an inventive clamp circuit for rounding the source potential according to FIG. 6 (curve e).

In all the figures in the drawing, identical or functionally identical elements, features and signals are, unless indicated otherwise, labeled with the same reference characters.

FIG. 4 shows with the aid of a first, general, exemplary embodiment a circuit arrangement for the PWM operation of an at least partially inductive load. In FIG. 4, the circuit arrangement is labeled with reference character 10 and a load with reference character 11. It is assumed hereinbelow that the load 11 is an electromagnetic injection valve and has an inductive part L1 and a resistive part R0. The inductive part L1, which forms the coil inductance L1, and the resistive part R0, which essentially emerges from the winding resistance, are arranged in series connection. Typical impedance values are 150 μH for the coil inductance L1 and approx. 0.5Ω for the coil resistance R0.

The circuit arrangement 10 also has two switching transistors T1, T2. In the present exemplary embodiment, the switching transistors are embodied as N-channel MOS power transistors (MOSFETs). The load 11 is arranged in series in relation to the controlled paths of the power MOSFETs T1, T2. The controlled path is understood in each case to be the drain-source path of the respective power MOSFET T1, T2. The load 11 is connected respectively to a load output of the power MOSFET T1, T2 such that the load 11 is consequently arranged between the two power MOSFETs T1, T2.

The series connection of power MOSFETs T1, T2 and load 11 is arranged between a first supply terminal 12 and a second supply terminal 13. A first supply potential VBB, for example the positive battery potential VBB, is applied to the first supply terminal, while a second supply potential GND, for example a negative supply potential or the ground reference potential GND, is applied to the second supply terminal 13. The power MOSFET T1 is consequently embodied as a high-side switch T1, while the power MOSFET T2 is embodied as a low-side switch T2.

The circuit arrangement can consequently be connected via the supply terminals 12, 13 to an energy supply 31, for example a DC voltage battery 31. Depending on the control of the power MOSFETs T1, T2, the load 11 and the coil inductance L1 can consequently have the supply voltage V+=VBB−GND applied.

The circuit arrangement 10 also has a free-wheeling diode D1 and a recuperation diode D2. Both diodes D1, D2 are embodied here as power diodes. The free-wheeling diode D1 is connected on the anode side to the second supply terminal 13 and on the cathode side to a tap 14. The tap 14 defines here a connection between the load-side output (source) of the high-side switch T1 and the load 11. The recuperation diode D2 is connected on the cathode side to the first supply terminal 12 and on the anode side to a tap 15 between the load 11 and the load-side output (drain) of the low-side switch T2.

For controlling the high-side switch T1, a control circuit 16 is provided. The control circuit 16 contains a clock generator 17 and a (power) driver 18. The control circuit 16 can be an integral part of a microcontroller or another program-controlled device or else embodied as a discrete control circuit 16, which is advantageous in particular for the driver 18 which, in order to control the power MOSFETs T1 has to supply a correspondingly high control current. The clock generator 17 generates on the output side a clock signal CLK which is fed to the driver 18 connected downstream. Depending on the clock signal CLK, the driver 18 generates on the output side a current signal IG which is fed to the control terminal G (gate) of the high-side switch T1. Control of the low-side switch T2 is effected via circuitry means (not shown in detail in FIG. 4), but can also be effected by means of the control circuit 16.

The high-side switch T1, the free-wheeling diode D1 and the coil inductance L1 of the load 11 form a PWM unit 19 of the inventive circuit arrangement 10.

According to the invention, a clamp circuit 20 is now provided which is connected to the control terminal G of the high-side switch T1. The clamp circuit 20 is embodied here as a simple switching diode D4 whose cathode is connected to the control terminal G of the high-side switch T1 and whose anode is connected to the supply terminal 13. The clamp circuit 20 functions here as an active clamp circuit 20 which, during a switch-off process, actively maintains the control potential VG at the control terminal G of the high-side switch T1 at a predetermined potential, namely the flow potential (−0.7 volts) of the switching diode D4.

The mode of operation of the inventive circuit arrangement 10 and in particular of the clamp circuit 20 will be briefly described below.

To switch the load 11, firstly the low-side switch T2 is closed. Subsequently or simultaneously, the high-side switch T1 is also closed. The switching-on of the high-side switch T1 is controlled by a control current signal IG of the driver 18. By means of the control current signal IG, the gate capacitance of the high-side switch T1 is charged up, as a result of which the gate-source voltage VGS rises in the same manner. Once the gate potential VG has reached a predetermined switch-on threshold Vth, then the current-carrying channel of the high-side switch T1 is opened and a drain current ID flows. The high-side switch T1 is now switched on. With the switching-on of the high-side switch T1, a current IL1 also flows through the coil inductance L1, as a result of which this coil inductance is charged up very rapidly. Due to the relatively low inductance, for example 15 μH, and the relatively high supply voltage V+≈48 volts, the coil current IL1 increases very rapidly. Once the coil current IL1 reaches a predetermined value, for example 20 A, then the electromagnetic injection valve assigned to the coil inductance L1 is opened.

In order to prevent the coil current IL1 from continuing to rise when the high-side switch T1 is closed, the high-side switch T1 is opened again. To this end, the control current signal IG is reset (for example to 0 amperes). Furthermore, the potential VG at the control terminal G of the high-side switch T1 is reduced, for example by a corresponding discharge current, until such time as the gate-source voltage VGS of the high-side switch T1 causes a pinching-off of the current-carrying channel (drain current). The high-side switch T1 is consequently opened again. After the opening of the high-side switch T1, the coil current IL1 continues to flow in this free-wheeling mode, driven by the coil inductance L1, via the free-wheeling diode D1, the coil inductance L1 and the low-side switch T2, the coil current IL1 slowly decaying.

Through periodic closing and opening of the high-side switch T1, (see also FIG. 2) a moderate coil current IL1 can in this way be generated in the coil inductance L1. For alternate closing, the control circuit switches to a PWM mode and generates a, for example, rectangular pulse-width-modulated control current signal IG.

If the valve assigned to the load 11 is to be closed again, for example when the fuel quantity required has been injected into the engine of the motor vehicle, then both MOSFETs T1, T2 are switched off or opened. The current I11 stored in the coil inductance L1 now flows via the free-wheeling diode D1, the load 11 and the recuperation diode D2. Due to the relatively high supply voltage V+≈48 volts, the coil current IL1 decays very rapidly, i.e. the valve is closed very rapidly.

As already mentioned in the introduction, during the process of switching off the high-side switch T1, it can happen, due to the energy stored in the parasitic line impedances, that the source terminal S of the high-side switch T1 exhibits in terms of magnitude a relatively high potential VS for a short period. These are referred to as voltage peaks when the high-side switch T1 is switched off. By means of the inventive clamp circuit 20, the control terminal G of the high-side switch T1 is now set to a predetermined gate potential VG, independently of the discharging process of the gate capacitance of the high-side switch T1. The effect of this is that while the control terminal G of the high-side switch T1 is discharged more slowly, which somewhat delays the switching-off process overall, the load-side terminal S of the high-side switch T1 is by this means advantageously also limited to a predetermined source potential VS.

FIG. 5 shows a second exemplary embodiment of an inventive circuit arrangement for the PWM operation of an inductive load, in which in particular the driver circuit 18 is shown in greater detail.

The driver circuit 18 has on the input side a switching transistor T3 whose control terminal and supply terminal are connected via switching resistances R1, R2 to the ground reference GND. The clock signal CLK of the clock generator 17 is consequently fed to the switching transistor T3. The switching transistor T3 generates on the output side a control-current signal S1.

The driver 18 also has a first current mirror 21, which is connected on the input side to the output 28 of the switching transistor T3. The first current mirror 21 has two current mirror resistances R3, R4 as well as a diode D3 and a switching transistor T4. The control terminal of the switching transistor T4 is controlled via the control-current signal S1. The first current mirror 21 is connected on the supply side to an auxiliary voltage source 22, which supplies for example an auxiliary voltage VHILF which is lower than the supply voltage V+≈=VBB−GND of the voltage supply source 31. For example, the auxiliary voltage is VHILF 12 volts, while the supply voltage is V+≈48 volts. The control-current signal S2 supplied by the first current mirror 21 at its output 19 depends substantially on the control-current signal S1, the ratio of the current mirror resistances R3, R4 and the amplification factor of the switching transistor T4.

The driver 18 also has a second current mirror 22 with two further current mirror resistances R5, R6 and a further switching transistor T5. On the input side, the second current mirror 22 is connected to the output 29 of the first current mirror such that the switching transistor T5 is controlled by the control-current signal S2 supplied on the output side by the first current mirror 21. The further current mirror 22 is connected on the supply side to the second supply terminal 13 for the ground reference GND. The second current mirror 22 is connected on the output side to a control terminal of the high-side switch T1 and controls this high-side switch with the control-current signal IG. By means of the current mirror resistances R5, R6 of the second current mirror 22, an appropriate ramp for the control-current signal IG and thus a through-switching time can be set.

The driver 18 also has a discharging circuit for discharging the gate capacitance of the high-side switch T1 and consequently for opening the high-side switch T1 in PWM mode. The discharging circuit has for this purpose a further switching diode D6. The switching diode D6 is arranged between the control terminal and the output 30 of the switching transistor T5 of the second current mirror 23. This switching diode D6 serves the purpose of enabling switching-on of the switching transistor T5 when the high-side switch T4 is switched off in order in this way to discharge the gate capacitance of the high-side switch T1 via the resistance R6.

The inventive clamp circuit 20 and the switching diode D4 are integral parts of the driver 18 in the exemplary embodiment in FIG. 5. Here, the switching diode D4 is arranged between the second supply terminal 13 and the control terminal G of the high-side switch T1.

As long as the gate potential VG is less than −0.7 volts and consequently greater than the flow voltage of the switching diode D4, the switching diode D4 locks. If the gate potential VG, driven by the discharge current flowing through the switching transistor T5 and the current mirror resistance R6, continues to fall, then the switching diode D4 becomes conductive and prevents a further reduction of the gate potential VG. Since the high-side switch T1 is operated in this configuration in a source-follower circuit, the source potential VS is now defined by the flow voltage of the switching diode D4 and the gate-source voltage VGS required for carrying the source current IS as follows:

VS=VD4+VGS

In the case of parasitic line inductances of about 30 nH, when the high-side switch T1 is switched off a source potential of about −5.6 volts is produced, which has to be taken into account in addition to the supply voltage V+=48 volts with respect to the loading of the high-side switch. Compared with a circuit arrangement without a clamp circuit, this represents a significant improvement.

FIG. 5 shows a particularly advantageous embodiment in which the two switching diodes D4, D6 of the clamp circuit 20 and of the discharging circuit are embodied as a double diode 24. In this arrangement, the cathodes 32 of the two switching diodes D4, D6 are short-circuited to one another.

The basic structure and the basic mode of operation of the driver 18 shown in FIG. 5 is described in detail in document DE 102 52 827, cited in the introduction, so that further detailed explanation of the structure and mode of operation thereof will be dispensed with hereinbelow. With respect to the structure and mode of operation of the driver circuit 18, the present patent application incorporates by reference the entire contents of this printed publication DE 102 52 827 B3.

FIG. 6 shows a third, more detailed exemplary embodiment of an inventive circuit arrangement for the PWM operation of an inductive load.

In contrast to the exemplary embodiment in FIG. 5, the extended circuit arrangement 10 in FIG. 6 has a device 25 which serves to round the source potential VS of the high-side switch T1. This device 25 is arranged between the second current mirror 23 and the second supply terminal 13. The device 25 has a capacitor C2 and a Zener diode D5 which are arranged in parallel with one another and which are connected by means of a resistor R7 to the supply terminal 26 of the second current mirror 23.

When the high-side switch T1 is switched on, the capacitor C2 is charged via the source terminal S of the high-side switch T1. The charging voltage of the capacitor C2 is limited here by the Zener diode D5 connected in parallel thereto to a predetermined voltage, for example to a voltage value of about 10 volts. If the high-side switch T1 is now switched off, then the gate potential VG drops, driven via the coil inductance L1, until it reaches a voltage value of about VG −≈0.7 volts below the charging voltage of the capacitor C2. As a result, the diode D4 becomes conductive. The capacitor C2 is now switched in parallel with the gate capacitance of the high-side switch T1, in particular the gate capacitances between gate and source terminal and gate and drain terminal, and accepts a portion of the discharging current flowing through the resistance R5 and the switching transistor T5. As a consequence, the gate potential VG drops and with it the source potential VS of the high-side switch T1 also decreases somewhat more slowly. The voltage at the capacitor C2 drops until such time as the Zener diode D5 downstream is polarized. The clamp circuit 20 previously described hereinabove with reference to FIG. 4 then takes effect, the function of the clamp circuit 20 then being effected by means of the switching diode D4 and additionally by means of the Zener diode D5, i.e. the clamping is carried out here on the basis of the flow voltages of the two diodes D4, D5.

Compared with the circuit arrangement in FIG. 5, the circuit arrangement in FIG. 6 represents a further possible advantageous embodiment in which a dynamic increasing of the anode potential of the switching diode D4 is carried out. To this end, a device 25 specifically provided for this purpose is supplied which enables a targeted rounding of the course of the source potential VS of the high-side switch T1 upon transition to free-wheeling.

FIG. 7 shows this correlation with the aid of three signal-time diagrams, the source potential VS of the high-side switch T1 being designated the signal, and parasitic line inductances in the region of about 30 nH having been assumed.

The curve designated c represents the source potential VS at the high-side switch T1 which occurs when the high-side switch T1 is switched off without an inventive clamp circuit 20 (see FIG. 3). A significant improvement is produced where an inventive clamp circuit 20 is used, as the curves d and e show. The curve d shows the source potential VS according to a circuit arrangement according to FIGS. 4 and 5. It is evident that a significant reduction of the source potential VS when the high-side switch is switched off can be achieved in this way. A further improved switching off characteristic, particularly with regard to EMC emission, is shown by curve e, in which a rounding of the source potential VS is produced upon switching off and a kink 27 can thus be avoided. A corresponding curve can be achieved, for example, using a circuit arrangement according to FIG. 6. Through the use of the circuit arrangement, a rounding off of the source potential VS is produced during a switch-off process, which is very advantageous, in particular with regard to the change in the source potential over time (dVS/dt) and thus with regard to EMC emission.

Although the present invention has been described hereinabove with the aid of preferred exemplary embodiments, it is not restricted thereto but can be modified in any manner.

In this way, the invention is not restricted exclusively to use in an electromagnetic injection valve but can be used with any inductive loads. Nor is a power MOSFET necessarily required in order to switch the load. Rather, additionally or alternatively, any other power switch and/or any other field-effect-controllable semiconductor component can be used for this purpose.

In the present invention, the inventive clamp circuit for limiting the control potential of the high-side switch has been implemented in a simple switching diode. The invention is not, however, restricted thereto but could also be implemented in any other manner, even though the use of a switching diode is especially preferred, in particular on cost grounds.

Instead of using a switching diode embodied as a discharging circuit, as shown in FIGS. 5 and 6, the discharging of the gate capacitance of the high-side switch can, additionally or alternatively, also be effected via a discharge resistor that is arranged, for example, between the gate terminal and source terminal thereof, or any other device.

1-16. (canceled)

17. A circuit arrangement for reducing load-side voltage peaks caused by parasitic line inductances when switching an at least partially inductive load, comprising:
at least one at least partially inductive load;
at least one high-side switch having a control terminal and having a controlled path connected in series with the load and between supply terminals for a supply voltage;
at least one free-wheeling diode connected to a first node between said high-side switch and the load; and
at least one clamp circuit connected to said control terminal of said high-side switch and configured to clamp a control potential applied to said control terminal and a load-side potential to a predetermined potential value when the high-side switch is switched off.

18. The circuit arrangement according to claim 17, wherein said clamp circuit includes a limiter diode biased towards said control terminal of said high-side switch, for clamping the control potential to a flow potential predetermined by said limiter diode.

19. The circuit arrangement according to claim 17, wherein said high-side switch is a switching transistor controlled by field effect.

20. The circuit arrangement according to claim 17, which comprises a first supply terminal with a first supply potential and a second supply terminal with a second supply potential lower than the first supply potential.

21. The circuit arrangement according to claim 20, wherein said clamp circuit is connected between said control terminal of said high-side switch and said second supply terminal.

22. The circuit arrangement according to claim 20, wherein said free-wheeling diode is connected between said node and said second supply terminal and conductively towards said node.

23. The circuit arrangement according to claim 17, which comprises a low-side switch having a controlled path connected in series with the load and a recuperation diode connected to a node between said low-side switch and the load.

24. The circuit arrangement according to claim 23, wherein at least one of said recuperation diode and said free-wheeling diode is a power diode.

25. The circuit arrangement according to claim 23, wherein at least one of said high-side switch and said low-side switch is a power MOSFET.

26. The circuit arrangement according to claim 25, wherein said power MOSFET is an n-channel power MOSFET.

27. The circuit arrangement according to claim 17, wherein said high-side switch is a power MOSFET.

28. The circuit arrangement according to claim 27, wherein said power MOSFET is an n-channel power MOSFET.

29. The circuit arrangement according to claim 17, wherein said free-wheeling diode is a power diode.

30. The circuit arrangement according to claim 17, wherein the at least partially inductive load is a coil inductance of an electromagnetic injection valve.

31. The circuit arrangement according to claim 17, which comprises a control circuit connected to and controlling said high-side switch, said control circuit including a driver supplying a control current for charging said control terminal of said high-side switch and switching on said high-side switch.

32. The circuit arrangement according to claim 31, which comprises a clock generator connected upstream of said driver, said clock generator supplying a clock signal for said driver for adjusting a pulse duty cycle of the control current.

33. The circuit arrangement according to claim 31, wherein said control circuit includes a discharge circuit, said discharge circuit, in order to switch off said high-side switch, generating a discharge current for discharging the control terminal of said high-side switch during a switch-off process of the high-side switch.

34. The circuit arrangement according to claim 31, wherein at least one of said control circuit and said clamp circuit includes a circuit arrangement for rounding a potential at a load-side output of said high-side switch, said circuit arrangement causing the control potential and the potential at the load-side output to decrease more slowly during a switch-off process of the high-side switch and upon transition to free-wheeling.

35. The circuit arrangement according to claim 17, wherein said free-wheeling diode of the high-side switch and the inductive load form a pulse-width modulated unit and the circuit arrangement comprises a multiplicity of pulse-width modulated units.

36. The circuit arrangement according to claim 35, wherein one low-side switch and one recuperation diode are connected to all said pulse-width-modulated units and, when both said high-side switch of at least one of said pulse-width modulated units is switched off and when said low-side switch is switched off, a charge stored in said inductive load is discharged via a current through said recuperation diode.
